(19) United States
(12) Patent Application Publication
(10) Pub. No.: US 2005/0024933 A1
(43) Pub. Date: Feb. 3, 2005

(54) Process for manufacturing device having selector transistors for storage elements and memory device fabricated thereby

(75) Inventors: Fabio Pellizzer, Follina (IT); Roberto Bez, Milano (IT)

Correspondence Address: SEED INTELLECTUAL PROPERTY LAW GROUP PLLC, 701 FIFTH AVENUE, SUITE 6300, SEATTLE, WA, 98104-7092, US

(73) Assignees: STMicroelectronics S.r.l., Agrate Brianza (IT); OVONYX Inc., Boise, ID (US)

(21) Appl. No.: 10/836,651

(22) Filed: Apr. 30, 2004

(30) Foreign Application Priority Data
May 7, 2003 (EP) 03425292.4

(51) Int. Cl. G11C 11/00

(52) U.S. Cl. 365/163

(57) ABSTRACT

A process for manufacturing a memory device having selector bipolar transistors for storage elements, includes the steps of: in a semiconductor body, forming at least a selector transistor, having at least an embedded conductive region, and forming at least a storage element, stacked on and electrically connected to the selector transistor; moreover, the step of forming at least a selector transistor includes forming at least a raised conductive region located on and electrically connected to the embedded conductive region.

### BACKGROUND OF THE INVENTION

1. Field of the Invention

The present invention relates to a process for manufacturing a memory device having selector transistors for storage elements and to a memory device fabricated thereby.

2. Description of the Related Art

As is known, memory devices comprise a plurality of memory cells or storage elements arranged in rows and columns, so as to form a memory array. Row and column decoders are used to selectively connect the storage elements to read/write circuits of the memory device for usual operation through. Moreover, in some cases it is necessary to provide further selection elements, which selectively activate and deactivate the storage elements for preventing disturbances caused by other adjacent storage elements.

To this aim, using bipolar transistors as selectors coupled to the storage elements is known as well. In particular, a bipolar selector transistor has a base terminal connected to a control line (e.g., a word line), an emitter terminal coupled to the storage element and a collector terminal normally connected to ground. It is clear that the way the emitter of the bipolar selector transistor and the storage element are coupled depends on the structure of the storage element itself.

For example, phase change memories are presently memory devices of increasing interest, which use bipolar transistors as selectors for storage elements.

Phase change memory cells utilize a class of materials that have the unique property of being reversibly switchable from one phase to another with measurable distinct electrical properties associated with each phase. For example, these materials may change between an amorphous disordered phase and a crystalline, or polycrystalline, ordered phase. A material property that may change and provide a signature for each phase is the material resistivity, which is considerably different in the two states.

Specific materials that may be suitably used in phase change cells are alloys of elements of the VI group of the periodic table as Te or Se, also called chalcogenides or chalcogenic materials. Therefore, hereinafter, the term “chalcogenic materials” is used to indicate all materials switchable between at least two different phases where they have different electrical properties (resistances) and include thus the elements of the VI group of the periodic table and their alloys.

In phase change memories, a thin film of chalcogenic material is employed as a programmable resistor, switching between a high and a low resistance condition.

Phase change is normally obtained by locally increasing the temperature. Under 150° C., both phases are stable. Over 200° C., nucleation of crystallites is fast and if the material is kept at the crystallization temperature for a sufficient time, it changes phase and becomes crystalline. In order to change the phase back to the amorphous state, its temperature is brought over the melting point (about 600° C.) and the calcogenide is rapidly cooled.

From an electrical point of view, it is possible to reach both critical temperatures (crystallization and melting temperatures) causing an electric current to flow through a resistive electrode in contact or close proximity with the chalcogenic material and heating the material by Joule effect. This goal is achieved by causing such a current flow to pass through a suitable neighboring series of resistors that operates as a heater.

The state of the chalcogenic material may be read by applying a sufficiently small voltage (or current) so as not to cause an appreciable heating and measuring the current passing through it (or voltage across it). Since the current is proportional to the conductance of the chalcogenic material (or voltage is proportional to the resistance), it is possible to discriminate between the two states.

There is always the need in the art for efficient and effective process for manufacturing memory devices and memory devices that provide, among others, high quality contacts between the selector and the storage element.

### BRIEF SUMMARY OF THE INVENTION

According to the present invention, one embodiment provides a process for manufacturing a memory device having selector transistors with raised contacts by forming a selector transistor having an embedded conductive region in a semiconductor body, forming one or more raised conductive regions on and electrically connected to the embedded conductive region, and forming a storage element that is stacked on and electrically connected to the embedded conductive region of the selector transistor.

Another embodiment of the present invention provides a memory device comprising a selector transistor and a storage element stacked on and electrically connected to the selector transistor, the selector transistor having a conductive region embedded in a semiconductor body, a plurality of raised conductive regions having sides and located on and electrically connected to the embedded conductive region, protective spacers positioned in contact with the sides of the raised conductive regions and covering areas of the embedded conductive region not in contact with the raised conductive layer, and a superficial layer of high conductivity on top of the raised conductive regions.

### BRIEF DESCRIPTION OF THE SEVERAL VIEWS OF THE DRAWINGS

For the understanding of the present invention, preferred embodiments thereof are now described, purely as non-limiting example, with reference to the enclosed drawings, wherein:

FIG. 1 is a cross-sectional view of a memory device of a known type;

FIG. 2 is a top plan view of a particular of FIG. 1, taken along line Il-II of FIG. 1;

FIGS. 3-5 are cross-sections through a semiconductor wafer in successive manufacturing steps of a process according to a first embodiment of the present invention;

FIG. 6 is a top plan view of the semiconductor wafer of FIG. 5;

FIGS. 7-16 are cross-sections through the semiconductor wafer of FIG. 5 in successive manufacturing steps;

FIG. 17 is a top plan view of a particular of FIG. 16, taken along line XVII-XVII of FIG. 16; and

FIGS. 18-22 are cross-sections through a semiconductor wafer in successive manufacturing steps of a process according to a second embodiment of the present invention.

### DETAILED DESCRIPTION OF THE INVENTION

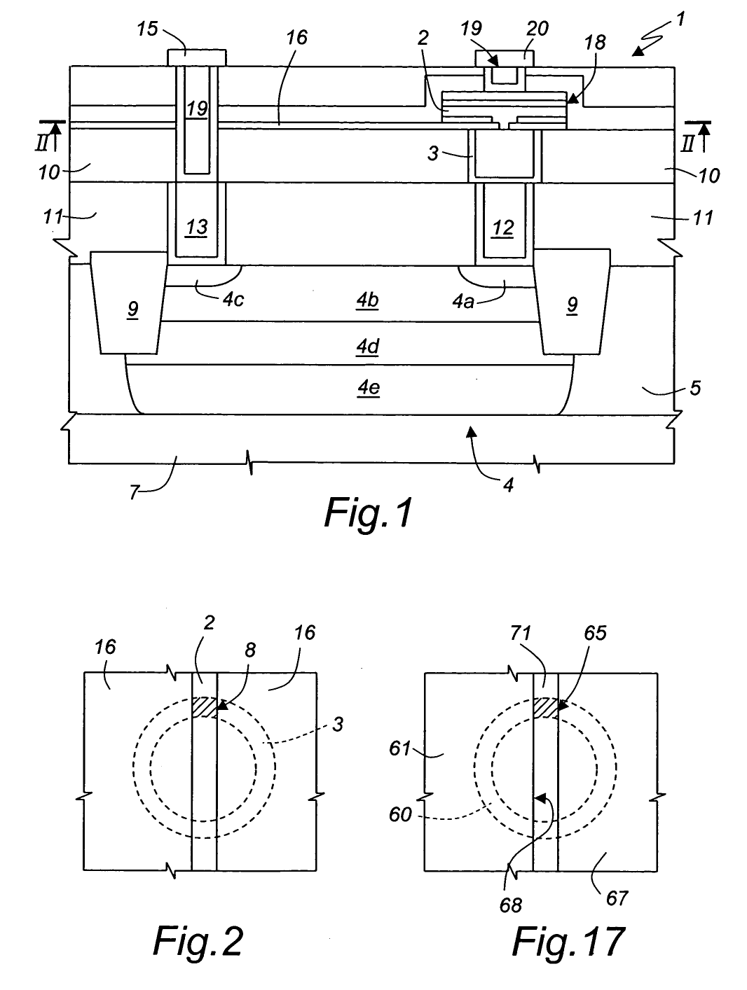

As already mentioned, bipolar selector transistors are coupled to the chalcogenic storage elements. For the sake of clarity, reference is made to FIG. 1, which illustrates a portion of a phase change memory device 1, comprising a chalcogenic strip 2, a cup-shaped heater 3, filled with dielectric material, and a selector 4; here, the selector 4 is a PNP bipolar transistor and is built in an epitaxial layer 5 grown over a substrate 7. In detail, the selector 4 comprises an emitter region 4a, a base region 4b, having a base contact region 4c, a collector region 4d and a sub-collector region 4e; moreover, the selector 4 is laterally delimited by trench isolation structures 9. A storage element 8 is defined at a contact region between the chalcogenic strip 2 and the heater 3, as schematically shown in FIG. 2. The heater 3 must be located a distance apart from the selector 4 and therefore is embedded in an upper dielectric layer 10, which is deposited on a lower dielectric layer 11. Moreover, the heater 3 is connected to the emitter region 4a of the selector 4 through a first plug 12, extending across the lower dielectric layer 11. A second plug 13 connects the base contact region 4c of the selector 4 to a word line 15.

According to known processes for fabricating phase change memories, the selector 4 is initially formed inside the epitaxial layer 5. Then, the lower dielectric layer 11 is deposited on the epitaxial layer 5 and the plugs 12, 13 are fabricated. More precisely, the lower dielectric layer 11 is anisotropically etched so as to form through openings, which are internally coated with a first conductive material and subsequently filled with a second conductive material.

The upper dielectric layer 10 is then deposited on the lower dielectric layer 11 and the heater 3 is made therein, by etching the upper dielectric layer 10, so as to open a cavity over the first plug 12, by coating the cavity with a material having a predetermined resistivity, thus contacting the first plug 12, and by filling the cavity again with dielectric material.

Thereafter, a delimiting layer 16 having an aperture is built on the upper dielectric layer 10; a chalcogenic layer is deposited on the delimiting layer 16 and fills the aperture, thereby forming the chalcogenic strip 2 and the storage element 8.

Finally, a metal line stack 18, second level plugs 19 and connection lines 20 are made, according to a required layout.

However, known processes have some limitations. First of all, a high number of fabrication steps are needed. For example, fabrication of the heater 3 preliminarily requires depositing the lower dielectric layer 11, for thermally insulating the selector 4 from the heater 3, forming the first plug 12 and the second plug 13 (i.e. etching the lower dielectric layer 11, internally coating and filling the openings), depositing and etching the upper dielectric layer 10; only at this stage of the process, resistive material can be deposited to form the heater 3.

Moreover, known processes can not provide high quality contacts between the terminals of the selector 4 and the storage element 8 or the connection lines. In fact, plugs 12, 13 land directly on doped epitaxial silicon of emitter region 4a and base contact region 4c, whereas further processing for making the surface of silicon contact regions highly conductive would be desirable.

It is clear that the above described drawbacks affect every type of memory cell using bipolar selector transistors coupled to the storage elements and not only phase change memories.

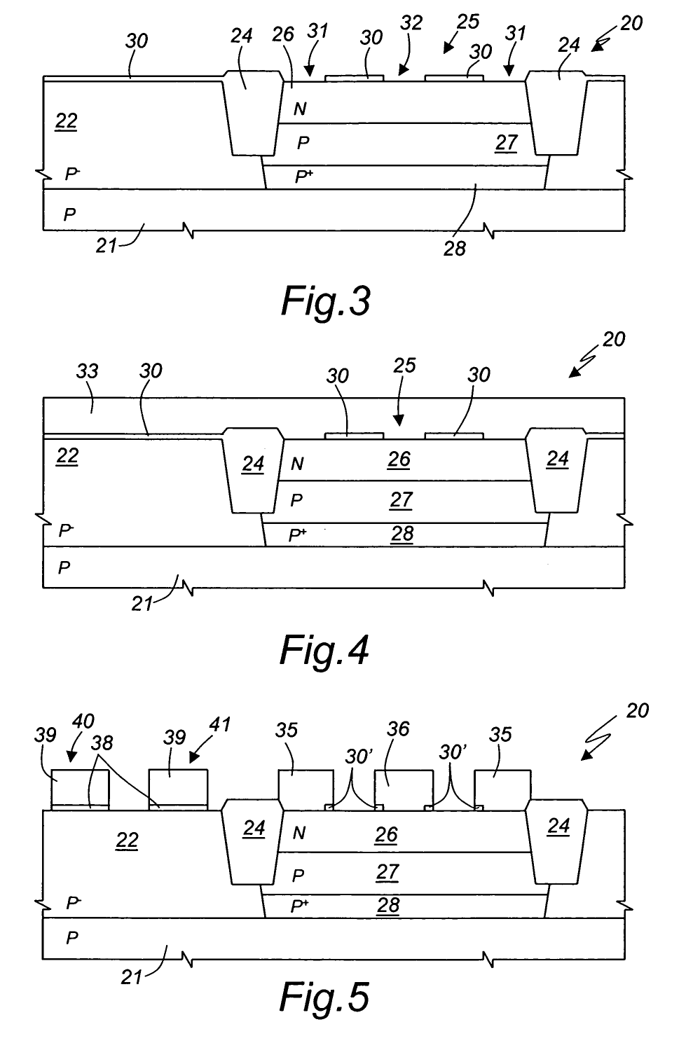

The present invention provides a process for manufacturing memory devices and a memory device that overcome the above described drawbacks. With reference to FIG. 3, a wafer 20 of semiconductor material comprises a substrate 21 and an epitaxial layer 22, for example of P type and of P− type, respectively. In an initial step of the process, a bipolar selector transistor 25 is formed within the epitaxial layer 22, in a per se known manner. In particular, the selector 25 is laterally delimited by trench isolation structures 24, preferably of silicon dioxide, and comprises a base region 26, of N type, a collector region 27, of P type, contiguous to the base region 26, and a sub-collector region 28, of P+ type and extending between the collector region 27 and the substrate 21.

A low-voltage gate oxide layer, hereinafter designed as LV oxide 30, is thermally grown on a whole surface 20a of the wafer 20 and is defined by a masked etch, so as to open emitter windows 31 and a base window 32, which partially expose corresponding contact areas of the base region 26. More precisely, the emitter windows 31 are formed at the ends of the base region 26 and are adjacent to the trench isolation structures 24, whereas the base window 32 exposes a central portion of the base region 26.

Subsequently, a polysilicon layer 33 of preferably 100-300 nm is deposited on the wafer 20 and entirely covers the LV oxide 30, as shown in FIG. 4. In practice, the polysilicon layer 33 and the base region 26 are separated from each other by the LV oxide 30; however, the polysilicon layer 33 extends through the emitter windows 31 and the base window 32, thus reaching the base region 26 at the exposed contact areas.

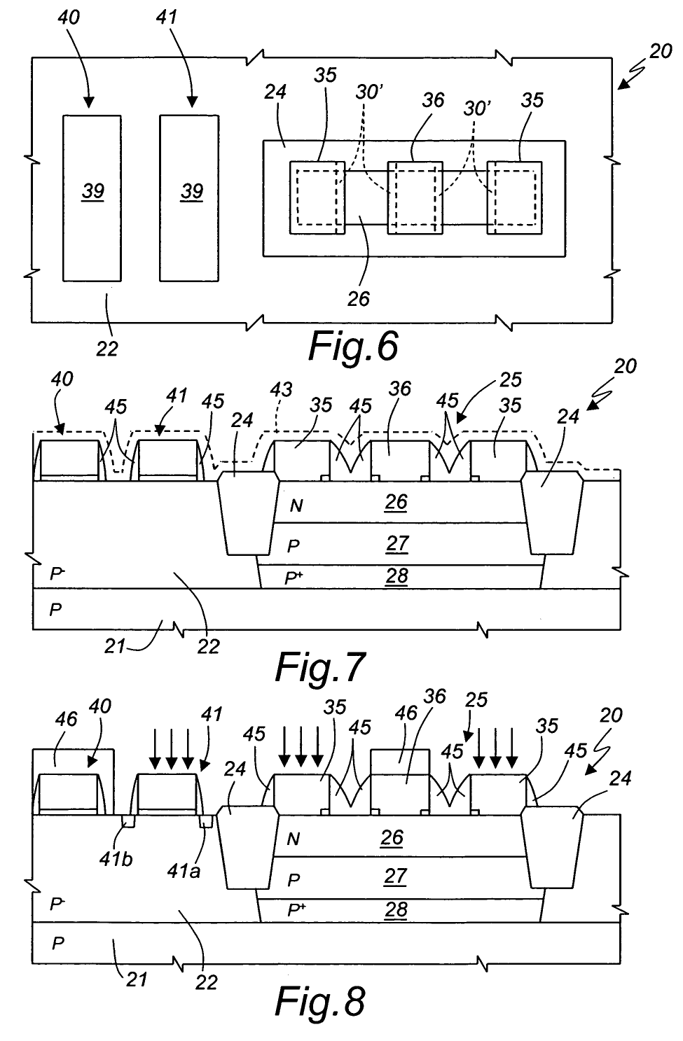

Thereafter (FIG. 5), the polysilicon layer 33 and the LV oxide 30 are selectively etched using a mask, here not illustrated. In detail, raised emitter regions 35 and a raised base region 36 are formed on the base region 26 of the selector 25, by removing the polysilicon layer 33 and the LV oxide 30 between the windows 31, 32. As shown in FIG. 6, the width of the raised emitter regions 35 and a raised base region 36 slightly exceeds the width of the base region 26. In this step, LV oxide 30 is at first used as a stop layer when the polysilicon layer 33 is etched, thus preventing the base region 26 from being damaged; then, the LV oxide 30 is etched as well. Raised emitter regions 35 and raised base region 36 are spaced by a predetermined distance, as explained hereinafter, and preferably overlap residual portions 30′ of the LV oxide 30; such residual portions 30′ are not removed to avoid the risk of leaving the base region 26 unprotected during polysilicon etch, on account of possible misalignments of the masks.

At the same time, on a circuitry portion of the wafer 20, which is schematically shown on the left of FIGS. 3-16, gate oxide regions 38 and gate regions 39 of NMOS transistors 40 and PMOS transistors 41 are formed.

A protecting layer 43, e.g., of silicon dioxide, illustrated with a dotted line in FIG. 7, is then formed on the entire wafer 20 and is anisotropically etched. In particular, the protecting layer 43 is completely removed from substantially flat or smoothed portions of the wafer 20, whereas steep regions remain covered by spacers 45. In other words, around the edges of the raised emitter regions 35, of the raised base region 36, and of the gate regions 39, the height of the protecting layer 43 is much greater than elsewhere. Accordingly, the protecting layer 43 is only partially removed, when anisotropically etched, since only portions having lower thickness are completely ablated. Hence, the spacers 45 are formed to protect the underlying regions. Furthermore, the raised emitter regions 35 and the raised base region 36 are reciprocally spaced by such a distance that adjacent spacers 45 join together. Hence, the entire base region 26 is covered by either the raised regions 35, 36, or the spacers 45.

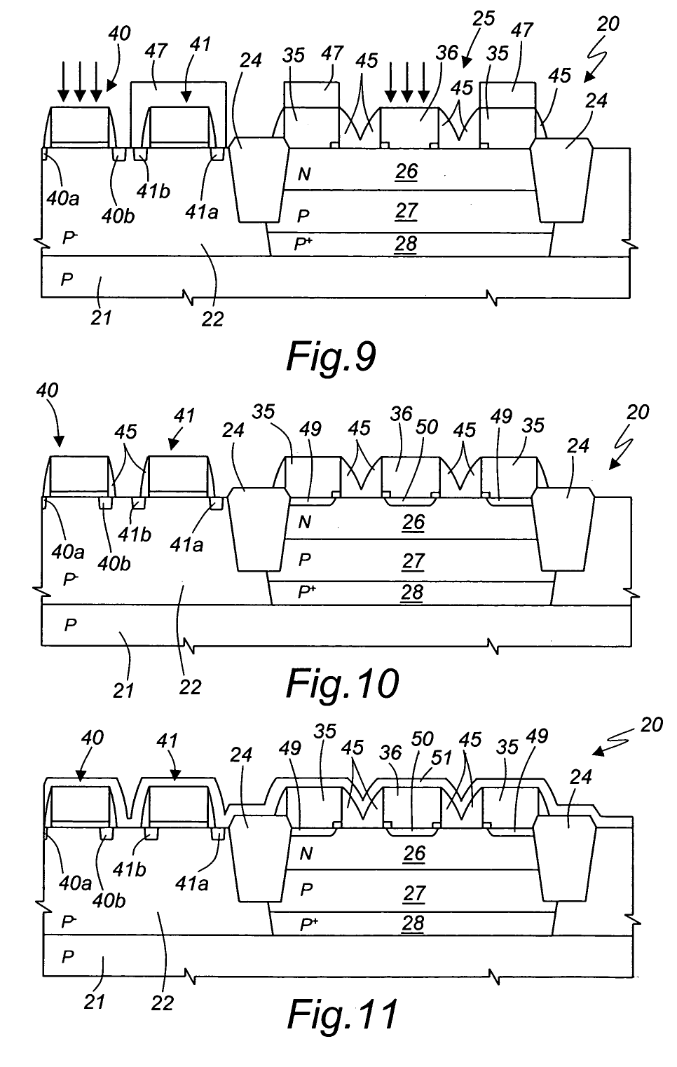

Subsequently, a P+ ion implantation and a N+ ion implantation are carried out (FIGS. 8 and 9). More precisely, during the P+ ion implantation, the raised emitter regions 35 and the gate regions 39 of PMOS transistors 41 are exposed to receive implanted ions, and the raised base region 36 and the gate regions 39 of NMOS transistors 40 are protected by a first mask 46; on the contrary, during N+ ion implantation the raised base region 36 and the gate regions 39 of NMOS transistors 40 are exposed and the raised emitter regions 35 and the gate regions 39 of PMOS transistors 41 are protected by a second mask 47. Moreover, during the P+ and N+ ion implantations, source regions 40a, 41a and drain regions 40b, 41b of the NMOS transistor 40 and of the PMOS transistor 41 are also formed in the epitaxial layer 22 (source regions 40a, 40b and drain regions 41a, 41b are only schematically sketched).

After the ion implantations, the wafer 20 is heated for diffusing and activating the implanted ions, as illustrated in FIG. 10. In practice, in this step embedded emitter regions 49, of P+ type, and a base contact region 50, of N+ type, are formed within the base region 26 under the raised emitter regions 35 and under the raised base region 36, respectively.

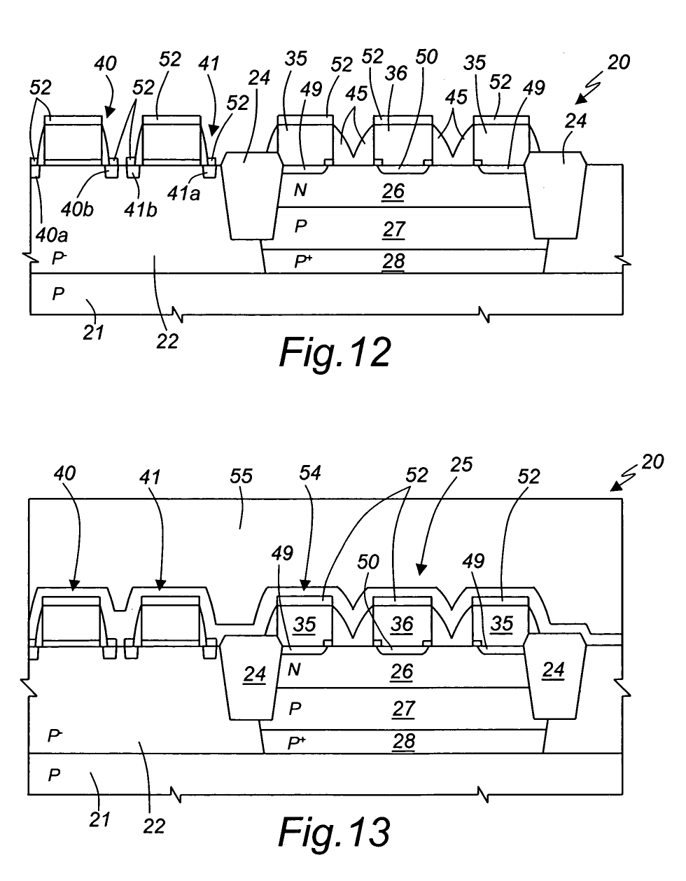

Then, a self-aligned silicidation step is carried out (FIGS. 11 and 12). In greater detail, a metallic layer 51, e.g., of Ti, is deposited on the wafer 20, which is heated; in regions where the metallic layer 51 is in direct contact with polysilicon or silicon, i.e. on raised regions 35, 36 and on MOS transistors 40, 41, metallic silicide regions 52 are formed (FIG. 12), having higher conductivity than even heavily doped polysilicon, by a factor of between about 10 and 100. Thereafter, by a selective etch, the metallic layer 51 is removed, whereas the silicide regions 52 are left. In practice, the metallic layer 51 is locally changed to metallic silicide, by exploiting silicon atoms of the underlying raised emitter regions 35 and of the raised base region 36. The suicide regions 52 thus form high conductivity superficial layers of the raised emitter regions 35 and of the raised base region 36. Since the self-aligned silicidation step exploits the conformation of the top surface of the wafer 20 and conductive regions which must be preserved from silicidation are protected by the spacers 45, no anti-silicidation mask is required.

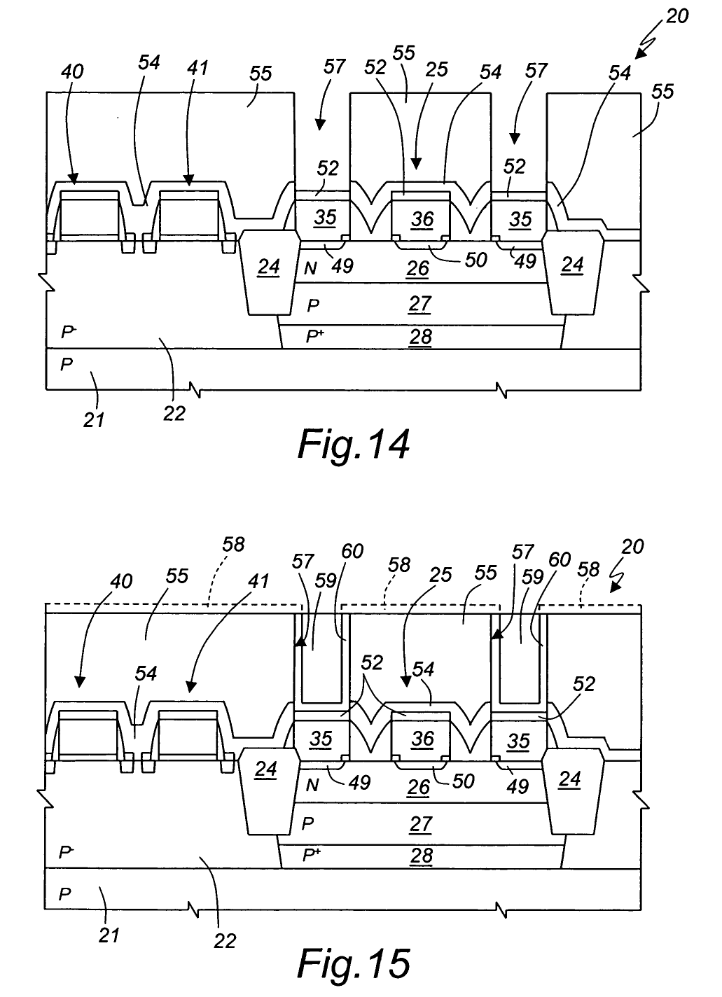

With reference to FIG. 13, a nitride layer 54 and a thick dielectric layer 55, higher than the raised regions 35, 36 and preferably made of silicon dioxide, are deposited on the wafer 20, which is then planarized, for example by CMP (Chemical-Mechanical-Polishing). Using a resist mask, not illustrated, the nitride layer 54 and the thick dielectric layer 55 are etched and first cavities 57 are opened, which extend down to the raised emitter regions 35, as shown in FIG. 14; more precisely, the first cavities 57 extend to the silicide regions 52 covering the raised emitter regions 35.

Subsequently, as shown in FIG. 15, a heating layer 58, having a predetermined resistivity, is deposited on the entire wafer 20 and coats the thick dielectric layer 55, walls of the first cavities 57 and the silicide regions 52 covering the raised emitter regions 35. Then, the first cavities 57 are filled with dielectric material 59. The dielectric material 59 and the heating layer 58 are removed by CMP from the thick dielectric layer 55 outside the first cavities 57. Residual portions of the heating layer 58 inside the first cavities 57 form heaters 60. Hence, heaters 60 are directly in contact with silicide regions 52 of respective raised emitter regions 35.

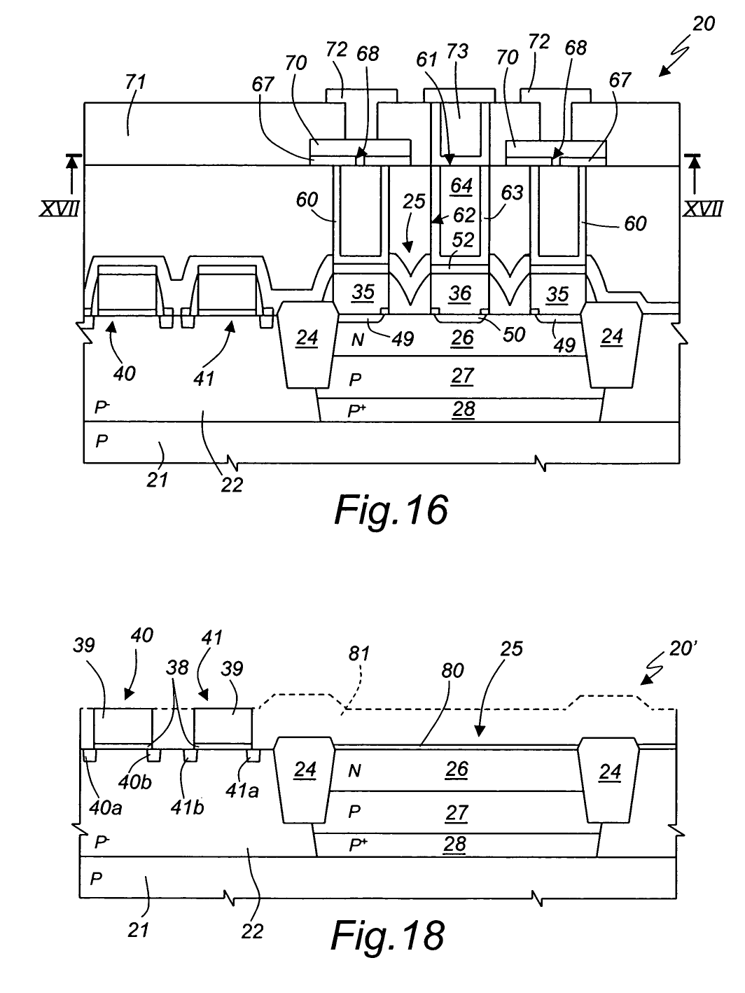

With reference to FIG. 16, a first level plug 61 is formed for providing electrical connection to the raised base region 36. In detail, a second cavity 62 is opened through the thick dielectric layer 55 and the nitride layer 54, so as to expose the suicide region 52 covering the raised base region 36; and a first conductive layer 63 is deposited inside the second cavity 62, which is filled with a second conductive layer 64.

Thereafter, storage elements 65 are made over the heaters 60 (see also FIG. 17), for example by forming a delimiting layer 67 having apertures 68 and by depositing and defining a chalcogenic layer 70, which fills the apertures 68. Accordingly, a memory device 75 is obtained, in which storage elements 65 are stacked on the selector 25 and the heaters 60; moreover, the storage elements 65 are connected to respective raised emitter regions 35 of the selector 25 through respective heaters 60.

Finally, an insulating layer 71 is deposited on the wafer 20; storage contacts 72 and a second level plug 73 are formed through insulating layer 71, so as to reach the storage elements 65 and the first level plug 61, respectively.

The advantages of the present invention are clear from the above. In particular, the process is quite simple with respect to the known processes. For example, in fact, silicidation step is self-aligned, since it is carried out exploiting the superficial conformation of the wafer and anti-silicidation mask is advantageously eliminated. Also, the heaters are made inside the dielectric layer which delimits the raised regions and therefore their fabrication does not require further deposition of dielectric layers.

Moreover, the present memory and manufacturing process allow a very efficient integration, completely compatible with CMOS technology and also with processes for the fabrication of chalcogenic storage elements with sublithographic dimension.

Also, selectors having raised emitter and/or base regions are provided, with high quality emitter and base contacts. In fact, raised regions can be easily silicided and the components that are coupled to the emitter and base contacts (i.e., heaters and first level plugs, respectively) land directly on silicide interfaces, which are much more conductive than polysilicon. Moreover, intermediate contacts are avoided.

A second embodiment of the present invention will be described hereinafter with reference to FIGS. 18-22, where parts already shown are indicated with the same reference signs as those in FIGS. 3-17.

In the early stages of the process, the selector 25 is formed inside a wafer 20′, which comprises the substrate 21, the epitaxial layer 22 and the trench isolation structures 24, as formerly described; moreover source regions 40a, 41a and drain regions 40b, 41b of transistors 40, 41 are formed in the substrate 22.

A LV oxide layer 80 and a polysilicon layer 81 are grown on the wafer 20′ and selectively etched for defining the gate oxide regions 38 and gate regions 39 of transistors 40, 41. The polysilicon layer 81 is removed from the base region 26.

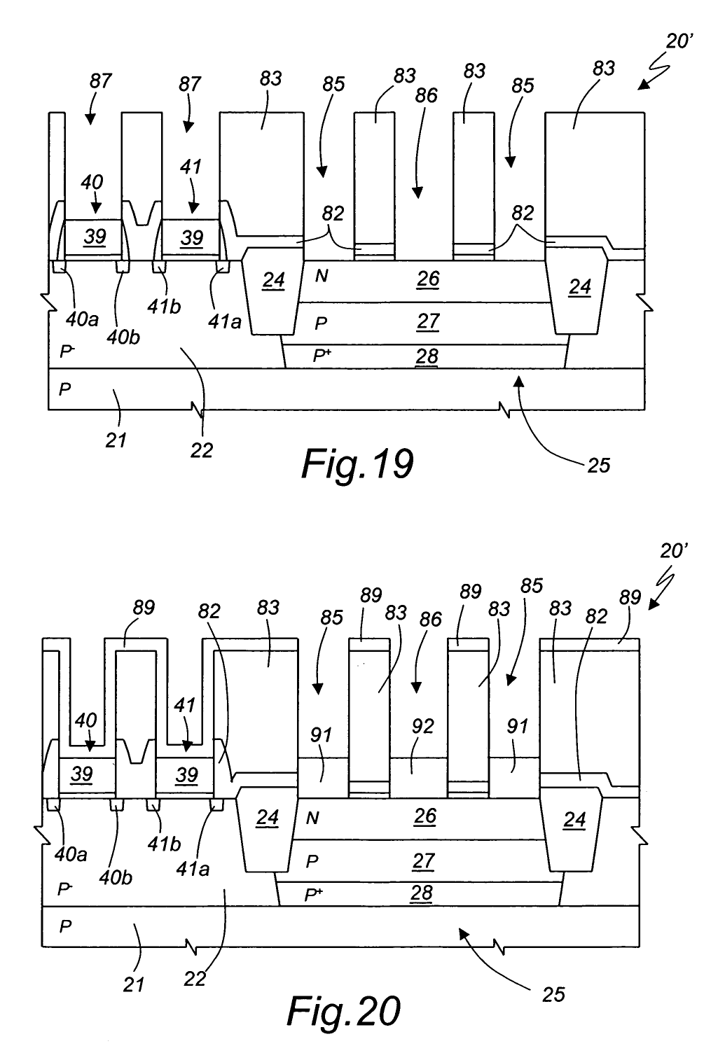

A nitride layer 82 and a dielectric layer 83 are then deposited, planarized by CMP and etched, so as to open emitter apertures 85 and a base aperture 86 over the base region 26, and gate apertures 87 over the gate regions 39 of the transistors 40, 41 (FIG. 19). The LV oxide layer 80 is then removed inside the emitter apertures 85 and the base aperture 86; hence, the base region 26 is partially exposed.

As illustrated in FIG. 20, a hard mask 89 is then formed, which protects the entire wafer 20′, except the emitter apertures 85 and the base aperture 86. Later on, an epitaxial growth step is carried out, during which epitaxial regions are formed over exposed portions of the base region 26. In detail, the epitaxial regions comprise raised emitter regions 91, inside the emitter apertures 85, and a raised base region 92, inside the base aperture 86.

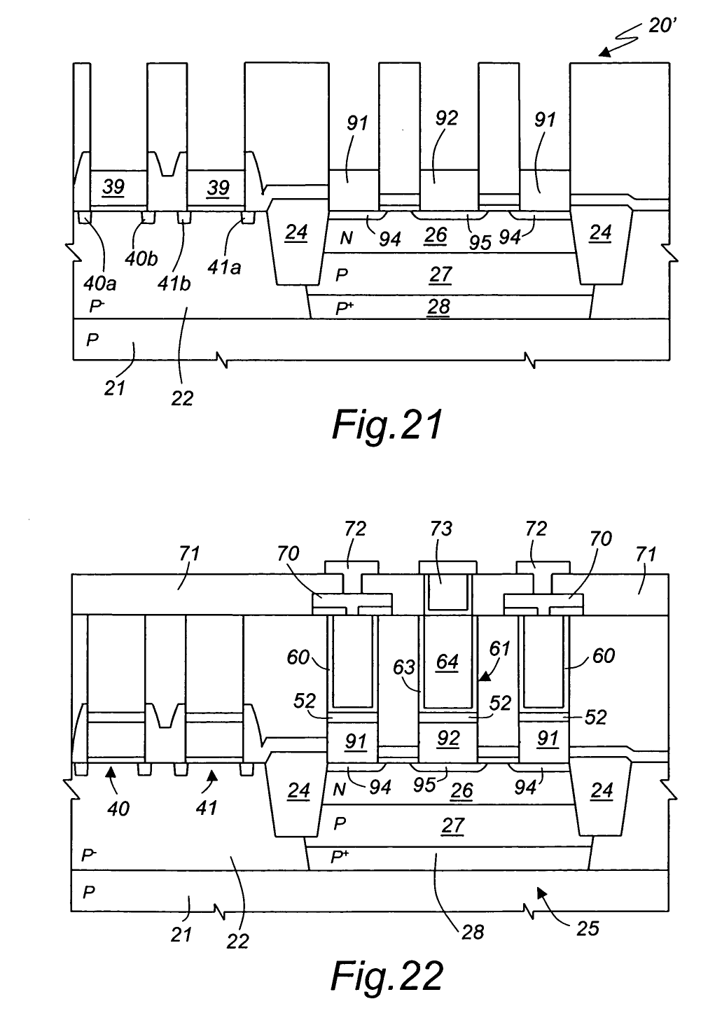

After removing the hard mask 89 (FIG. 21), P+ and N+ ion implantations are performed and implanted ions are then diffused and activated. Thus, embedded emitter regions 94, of P+ type, and a base contact region 95, of N+ type, are formed within the base region 26 under the raised emitter regions 91 and under the raised base region 92, respectively.

The process is then continued as already described. In particular, after a self-aligned silicidation step, the heaters 60, the storage elements 65 (see FIG. 17), the storage contacts 72 and the plugs 61, 73 are made, as shown in FIG. 22; a memory device 100 is thus obtained.

Finally, it is clear that numerous variations and modifications may be made to process and to the memory device described and illustrated herein, all falling within the scope of the invention as defined in the attached claims.

First, the process can be exploited for manufacturing any kind of memories that require bipolar selector transistors coupled to the storage elements, and not only phase change memories.

The selector 25 can comprise either a single raised emitter or even more than two raised emitters. Moreover, the selector 25 could have only raised emitter regions, whereas the base contact is of a standard type. In this case, the LV oxide 30 is removed only to open emitter windows 31 and is left elsewhere over the base region 26. After building the spacers 45, a portion of the base region 26 is exposed, so that it first receives N+ type dopant ions, and then is coated by a silicide region during silicidation. Also in this case, silicidation is self-aligned and anti-silicidation mask is not required. A deeper first level plug is formed later, since it has to go through all the thickness of the thick dielectric layer 55; anyway the quality of the base contact is not impaired.

When standard base contacts are made, the LV oxide 30 can be completely etched over the base region 26, before depositing the polysilicon layer 33 directly on the base region 26 itself. The polysilicon layer 33 is then etched as described, for defining the raised emitter regions 35 over the base region 26 and the gate regions 39 in circuitry area; the etch of the polysilicon layer 33 is stopped as soon as the residual LV oxide 30 in the circuitry area is reached and a slight over-etch of the base region 26 is acceptable.

The first and second level plugs 61 and 73 can be replaced by a single level plug, thus simplifying the process.

At last, it is clear that the selector 25 can be also a bipolar NPN transistor.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A process for manufacturing a memory device having selector transistors with raised contacts, comprising the steps of:
in a semiconductor body, forming a selector transistor having an embedded conductive region; and
forming at least a storage element, stacked on and electrically connected to said selector transistor, wherein forming the selector transistor includes forming a raised conductive region located on and electrically connected to said embedded conductive region.

2. A process according to claim 1, wherein said step of forming the raised conductive region comprises forming a plurality of raised conductive regions.

3. A process according to claim 1, wherein said step of forming the selector transistor comprises forming a bipolar transistor, said embedded conductive region being a base region of said bipolar transistor.

4. A process according to claim 3, wherein said step of forming the raised conductive region comprises forming a plurality of raised emitter regions.

5. A process according to claim 3, wherein said step of forming the raised conductive region comprises forming a raised emitter region and a raised base region.

6. A process according to claim 1, wherein said step of forming the raised conductive region comprises the steps of:
growing a separation layer on said embedded conductive region;
selectively etching said separation layer to provide exposed areas on parts of said embedded conductive region;
forming a conductive layer on said separation layer, said conductive layer reaching said exposed areas of said embedded conductive region; and
etching said conductive layer, substantially over said separation layer.

7. A process according to claim 6, wherein, after said step of etching said conductive layer, said separation layer is removed.

8. A process according to claim 7, wherein said step of removing said separation layer comprises leaving residual portions of said separation layer and wherein said step of etching said conductive layer comprises leaving portions of said conductive layer overlapping said residual portions.

9. A process according to claim 1, wherein said step of forming the raised conductive region comprises the steps of:
forming a conductive layer directly on said embedded conductive region; and
etching said conductive layer.

10. A process according to claim 1, wherein said raised conductive region is silicided.

11. A process according to claim 10, wherein, before siliciding said raised conductive region, protective structures are formed on sides of said raised conductive region.

12. A process according to claims 11 wherein said step of forming the raised conductive region comprises forming a plurality of raised conductive regions and said raised conductive regions are spaced by such a distance that adjacent protective structures join together.

13. A process according to claim 1, wherein said step of forming the raised conductive region comprises epitaxially growing said raised conductive region.

14. A process according to claim 1, wherein said step of forming the storage element comprises forming a phase change storage element.

15. A process according to claim 14, wherein a heater is formed directly in contact with said raised conductive region, and said storage element is formed directly in contact with said heater.

16. A memory device comprising:
a selector transistor having a conductive region embedded in a semiconductor body and a raised conductive region located on and electrically connected to said embedded conductive region; and
a storage element stacked on and electrically connected to said selector transistor;

17. A memory device according to claim 16, wherein said selector transistor comprises a plurality of raised conductive regions located on and electrically connected to said embedded conductive region.

18. A memory device according to claim 16, wherein said selector transistor comprises a bipolar transistor, said embedded conductive region being a base region of said bipolar transistor.

19. A memory device according to claim 18, wherein said selector transistor comprises a plurality of raised emitter regions.

20. A memory device according to claim 18, wherein the raised conductive region is a raised base region and said selector transistor comprises a raised emitter region.

21. A memory device according to claim 16, wherein said raised conductive region has a superficial layer of high conductivity.

22. A memory device according to claim 21, wherein said superficial layer of high conductivity is a metallic silicide layer.

23. A memory device according to claim 16, wherein said storage element is a phase change storage element.

24. A memory device according to claim 23, wherein a heater is located between said raised conductive region and said storage element, said heater being directly in contact with said raised conductive region and with said storage element.

25. A memory device according to claim 17 wherein said plurality of raised conductive regions are separated by protective spacers, said protective spacers covering areas of said embedded conductive region not in contact with said raised conductive regions.

26. A memory device according to claim 25 wherein said protective spacers are silicon oxide.

27. A memory device according to claim 25 further comprising a superficial layer of high conductivity on top of the raised conductive regions.

28. A memory device according to claim 27 wherein said superficial layer is a metal silicide layer.

29. A memory device comprising a selector transistor and a storage element stacked on and electrically connected to said selector transistor, wherein said selector transistor comprises:
an embedded conductive region in a semiconductor body;
a plurality of raised conductive regions having sides and located on and electrically connected to said embedded conductive region;
protective spacers positioned in contact with the sides of said raised conductive regions, wherein, the protective spacers cover areas of said embedded conductive region not in contact with said raised conductive layer; and
a superficial layer of high conductivity on top of said raised conductive regions.

30. A memory device of claim 29 wherein the superficial layer is a metal silicide layer.

31. A memory device of claim 29 further comprising a heater between and in direct contact with said raised conductive region and said storage element.

32. A memory device of claim 29 wherein said storage element is a phase change storage element.
